(19) United States
(12) Patent Application Publication
(10) Pub. No.: US 2004/0076902 A1
(43) Pub. Date: Apr. 22, 2004

(54) Chemical amplification type positive resist composition

(76) Inventors: Junji Nakanishi, Kyoto-shi (JP); Katsuhiko Namba, Osaka (JP)

Correspondence Address: BIRCH STEWART KOLASCH & BIRCH, PO BOX 747, FALLS CHURCH, VA, 22040-0747, US

(21) Appl. No.: 10/271,754

(22) Filed: Oct. 17, 2002

(30) Foreign Application Priority Data
Oct. 17, 2002 (JP) 2001-321711

(51) Int. Cl. G03F 7/004; G03F 7/039

(52) U.S. Cl. 430/270.1; 430/966; 430/942; 430/922

(57) ABSTRACT

A chemical amplification type positive resist composition, which can attain high sensitivity while maintaining high resolution, and comprises (A) a compound of the following formula (I):

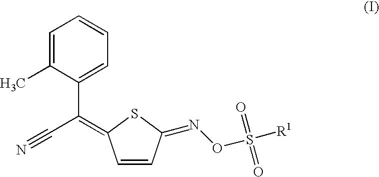

wherein, R¹ represents a hydrocarbon group optionally having a substituent containing an oxygen atom or nitrogen atom or being optionally substituted by a halogen atom; (B) a resin which itself is insoluble or poorly soluble in an alkaline aqueous solution but becomes soluble in an alkaline aqueous solution by the action of an acid; and (C) a quaternary ammonium salt is provided.

### BACKGROUND OF THE INVENTION

1. Field of the Invention

The present invention relates to a resist composition suitable for lithography acting by radiation of high energy such as ultraviolet ray (including g line, i line, excimer laser and the like), electron beam, X ray, emitting light and the like, particularly suitable for exposure with g line and i line.

2. Prior Art

Conventionally, in production of liquid crystal elements and the like, positive resist compositions comprising a novolak resin and a naphthoquinonediazide based sensitive material are used. Resist compositions used in production of liquid crystal elements and the like are desired to have high sensitivity and high resolution. However, these positive resist compositions comprising a novolak resin and a naphthoquinonediazide based sensitive material are, in general, difficult to satisfy high sensitivity and to give high resolution simultaneously, and enhanced resolution tends to invite reduction in resolution. Positive resists include also a chemical amplification type resist comprising a resin which becomes alkali-soluble by the action of an acid from a condition insoluble or poorly soluble in an alkali aqueous solution, and an acid generator. However, in such a chemical amplification type resist, if a compound of the following formula (I)

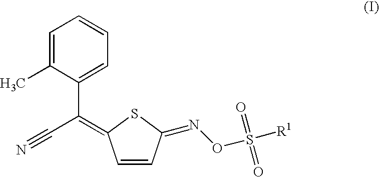

wherein, R¹ represents a hydrocarbon group optionally having a substituent containing an oxygen atom or nitrogen atom or being optionally substituted by a halogen atom, is used as the acid generator, the profile of a resist deteriorates extremely, and intended resolution is not obtained.

### SUMMARY OF THE INVENTION

The object of the present invention is to provide a positive resist composition having extremely enhanced sensitivity, while maintaining high resolution.

The present inventors have intensively studied for attaining such an object, and resultantly found that a positive resist composition comprising a quaternary ammonium salt, in addition to a compound of the formula (I) and a resin which itself is insoluble or poorly soluble in an alkaline aqueous solution but becomes soluble in an alkaline aqueous solution by the action of an acid, can get extremely enhanced sensitivity while maintaining high resolution. Thus, the present invention was completed.

The present invention provides to a chemical amplification type positive resist composition comprising (A) a compound of the formula (I), (B) a resin which itself is insoluble or poorly soluble in an alkaline aqueous solution but becomes soluble in an alkaline aqueous solution by the action of an acid, and (C) a quaternary ammonium salt.

### DETAILED DESCRIPTION OF PREFERRED EMBODIMENTS

In the resist composition of the present invention, the resin component itself is insoluble or poorly soluble in an alkali but becomes alkali-soluble by causing a chemical change by the action of an acid. Examples of such resins include a resin obtained by introducing a protective group dissociable by the action of an acid into a resin soluble in an alkali aqueous solution such as a resin having a phenol skeleton and a resin having a (meth) acrylic acid skeleton. Such a group having a dissolution inhibiting ability to an alkali aqueous solution (an alkali developer) but unstable to an acid can be selected from various known protective groups.

Examples thereof include groups in which a quaternary carbon is bonded to an oxygen atom such as tert-butyl, tert-butoxycarbonyl or tert-butoxycarbonylmethyl; acetal type groups such as tetrahydro-2-pyranyl, tetrahydro-2-furyl, 1-ethoxyethyl, 1-(2-methylpropoxy)ethyl, 1-(2-methoxyethoxy)ethyl, 1-(2-acetoxyethoxy)ethyl, 1-[2-(1-adamantyloxy)ethyl]ethyl or 1-[2-(1-adamantanecarbonyoxy)ethoxy]ethyl; and non-aromatic cyclic compounds residue such as 3-oxocyclohexyl, 4-methyltetrahydro-2-pyron-4-yl (derived from mevalonic lactone), 2-methyl-2-adamantyl, and 2-ethyl-2-adamantyl. Among them, 1-ethoxyethyl group is preferable since it has high stability to post exposure delay. Therefore, as the component (B) in the present invention, preferable is a resin containing a polymerization unit having a structure formed by partially protecting a phenolic hydroxyl group with a 1-ethoxyethyl group. Specifically, preferable as the component (B) is a resin obtained by partially protecting a hydroxyl group in polyvinylphenol with a 1-ethoxyethyl group or a resin obtained by partially protecting a hydroxyl group in a novolak resin with a 1-ethoxyethyl group.

The protective groups such as those exemplified above are substituted for hydrogen on a phenolic hydroxyl group or hydrogen on a carboxyl group. These protective groups can be introduced into an alkali-soluble resin having a phenolic hydroxyl group or carboxyl group by a known protective group introduction reaction. Further, the above-mentioned resin can be obtained also by copolymerization using, as one monomer, an unsaturated compound having such a group.

The resist composition of the present invention can comprise, as a binder component, a resin soluble in an alkali aqueous solution (hereinafter, called an alkali-soluble resin in some cases) in an amount not deteriorating the effect of the present invention. As the alkali-soluble resin, novolak resins and the like are listed.

A novolak resin is usually obtained by condensation of a phenol-based compound and an aldehyde in the presence of an acid catalyst. Examples of the phenol-based compound used in production of the novolak resins include phenol, o-, m- or p-cresol, 2,3-, 2,5-, 3,4- or 3,5-xylenol, 2,3,5-trimethylphenol, 2-, 3- or 4-tert-butylphenol, 2-tert-butyl-4- or 5-methylphenol, 2-, 4- or 5-methylresorcinol, 2-, 3- or 4-methoxyphenol, 2,3-, 2,5- or 3,5-dimethoxyphenol, 2-methoxyresorcinol, 4-tert-butylcatechol, 2-, 3- or 4-ethylphenol, 2,5- or 3,5-diethylphenol, 2,3,5-triethylphenol, 2-naphthol, 1,3-, 1,5- or 1,7-dihydroxynaphthalene, polyhydroxytriphenylmethane-based compounds obtained by condensation of xylenol and hydroxybenzaldehyde, and the like. These phenol compounds can be used alone or in combination of two or more.

Examples of the aldehyde used in production of the novolak resin include aliphatic aldehydes such as formaldehyde, acetaldehyde, propionaldehyde, n-butylaldehyde, isobutylaldehyde, acrolein or crotonaldehyde; alicyclic aldehydes such as cyclohexanealdehyde, cyclopentanealdehyde, furfural or furylacrolein; aromatic aldehydes such as benzaldehyde, o-, m- or p-methylbenzaldehyde, p-ethylbenzaldehyde, 2,4-, 2,5-, 3,4- or 3,5-dimethylbenzaldehyde or o-, m- or p-hydroxybenzaldehyde; aromatic aliphatic aldehydes such as phenylacetaldehyde or cinnamic aldehyde; and the like. These aldehydes can also be used each alone or in combination of two or more if necessary. Of these aldehydes, formaldehyde is preferably used since it is industrially obtainable easily.

Examples of the acid catalyst used in condensation of a phenol-based compound with an aldehyde include inorganic acids such as hydrochloric acid, sulfuric acid, perchioric acid or phosphoric acid; organic acids such as formic acid, acetic acid, oxalic acid, trichloroacetic acid or p-toluenesulfonic acid; divalent metal salts such as zinc acetate, zinc chloride or magnesium acetate. These acid catalysts can also be used each alone or in combination of two or more. The condensation reaction can be conducted according an ordinary method, for example, conducted at temperatures in the range from 60 to 120° C. for about 2 to 30 hours.

Regarding novolak resins obtained by condensation, it is possible that components of lower molecular weight are removed by performing operations such as fractionation and the like, for narrowing the molecular weight distribution, to give a resin mainly composed of components of higher molecular weights. Since novolak resins are less costly, it is useful to reduce the cost of resist.

The acid generator in the composition of the present invention are substances generating an acid by irradiating the substance itself or a resist composition containing this substance with radiation such as a light or an electron beam. In a chemical amplification type positive resist composition, an acid generated from an acid generator will act on the above-mentioned resin, to dissociate a group unstable to an acid present in the resin.

In the present invention, a compound of the formula (I) showing large absorption around 436 nm (g line) and 365 nm (i line) is used as the acid generator, the component (A).

Examples of the hydrocarbon group R¹ in the formula (I) include alkyl groups having 1 to 12 carbon atoms and aryl groups having 6 to 18 carbon atoms. Examples of the substituent having an oxygen atom or nitrogen atom include ester groups, hydroxyl group, alkoxyl groups, oxo group and nitro group. As the halogen atom, fluorine, chlorine, bromine and the like are listed.

Specific examples as the compound of the formula (I) include those of the formula (I) in which R¹ represents a n-propyl group, n-butyl group, n-octyl group, toluyl group, 2,4,6-trimethylphenyl group, 2,4,6-triisopropylphenyl group, 4-dodecylphenyl group, 4-methoxyphenyl group, 2-naphthyl group, benzyl group, or a group of the following formula (II).

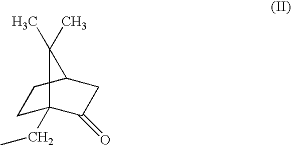

In the resist composition of the present invention, an acid generator other than the above acid generator of formula (I) can be co-used. Examples of such another acid generator include onium salt compounds, s-triazine-based organic halogen compounds, sulfone compounds, sulfonate compounds and the like. Specifically, the following compounds are listed.

Diphenyliodonium trifluoromethanesulfonate,

4-methoxyphenylphenyliodinium hexafluoroantimonate,

4-methoxyphenylphenyliodinium trifluoromethanesulfonate,

bis(4-tert-butylphenyl)iodonium tetrafluoroborate

bis(4-tert-butylphenyl)iodonium hexafluorophosphate,

bis(4-tert-butylphenyl)iodonium hexafluoroantimonate

bis(4-tert-butylphenyl)iodonium trifluoromethanesulfonate,

triphenylsulfonium hexafluorophosphate,

triphenylsulfonium hexafluoroantimonate,

triphenylsulfonium trifluoromethanesulfonate,

4-methylphenyldiphenylsulfonium perfluorobutanesulfonate,

4-methylphenyldiphenylsulfonium perfluorooctanesulfonate,

4-methoxyphenyldiphenylsulfonium hexafluoroantimonate,

4-methoxyphenyldiphenylsulfonium trifluoromethanesulfonate,

p-tolyldiphenylsulfonium trifluoromethanesulfonate,

2,4,6-trimethylphenyldiphenylsulfonium trifluoromethanesulfonate,

4-tert-butylphenyldiphenylsulfonium trifluoromethanesulfonate,

4-phenylthiophenyldiphenylsulfonium hexafluorophosphate,

4-phenylthiophenyldiphenylsulfonium hexafluoroantimonate,

1-(2-naphtholylmethyl)thiolanium hexafluoroantimonate,

1-(2-naphtholylmethyl)thiolanium trifluoromethanesulfonate,

4-hydroxy-1-naphthyldimethylsulfonium hexafluoroantimonate,

4-hydroxy-1-naphthyldimethylsulfonium trifluoromethanesulfonate,

2-methyl-4,6-bis(trichloromethyl)-1,3,5-triazine

2,4,6-tris(trichloromethyl)-1,3,5-triazine

2-phenyl-4,6-bis(trichloromethyl)-1,3,5-triazine,

2-(4-chlorophenyl)-4,6-bis(trichloromethyl)-1,3,5-triazine,

2-(4-methoxyphenyl)-4,6-bis(trichloromethyl)-1,3,5-triazine,

2-(4-methoxy-1-naphthyl)-4,6-bis(trichloromethyl)-1,3,5-triazine,

2-(benzo[d][1,3]dioxolan-5-yl)-4,6-bis(trichloromeythyl)-1,3,5-triazine,

2-(4-methoxystyryl)-4,6-bis(trichloromethyl)-1,3,5-triazine,

2-(3,4,5-trimethoxystyryl)-4,6-bis(trichloromethyl)-1,3,5-triazine,

2-(3,4-dimethoxystyryl)-4,6-bis(trichioromethyl)-1,3,5-triazine,

2-(2,4-dimethoxystyryl)-4,6-bis(trichloromethyl)-1,3,5-triazine,

2-(2-methoxystyryl)-4,6-bis(trichloromethyl)-1,3,5-triazine,

2-(4-butoxystyryl)-4,6-bis(trichloromethyl)-1,3,5-triazine,

2-(4-pentyloxystyryl)-4,6-bis(trichloromethyl)-1,3,5-triazine,

1-benzoyl-1-phenylmethyl p-toluenesulfonate (generally called benzoin tosylate),

2-benzoyl-2-hydroxy-2-phenylethyl p-toluenesulfonate (generally called α-methylolbenzointosylate),

1,2,3-benzenetolyl trismethanesulfonate,

2,6-dinitrobenzyl p-toluenesulfonate,

2-nitrobenzyl p-toluenesulfonate,

4-nitrobenzyl p-toluenesulfonate,

diphenyl disulfone,

di-p-tolyl disulfone

dis(phenylsulfonyl)diazomethane,

bis(4-chlorophenylsulfonyl)diazomethane,

bis(p-tolylsulfonyl)diazomethane,

bis(4-tert-butylphenylsulfonyl)diazomethane,

bis(2,4-xylylsulfonyl)diazomethane,

bis(cyclohexylsulfonyl)diazomethane,

(benzoyl)(phenylsulfonyl)diazomethane,

N-(phenylsulfonyloxy)succinimide,

N-(trifluoromethylsulfonyloxy)succinimide,

N-(trifluoromethylsulfonyloxy)phthalimide,

N-(trifluoromethylsulfonyloxy)-5-norbornene-2,3-dicarboxyimide,

N-(trifluoromethylsulfonyloxy)naphthalimide,

N-(10-camphorsulfonyloxy)naphthalimide,

4-methoxy-α-[[[(4-methylphenyl)sulfonyl]oxy]imino]benzeneacetonitrile, and the like.

As the quaternary ammonium salt contained in the resist composition of the present invention, compounds of the following general formula (III)

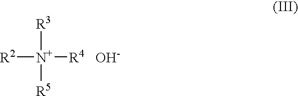

are preferable.

In the formula, R² to R⁵ each independently represent a hydrocarbon group optionally having a substituent containing an oxygen atom or nitrogen atom, or being optionally substituted by a halogen atom. Some of R² to R⁵ groups may together form a cyclic structure.

Specific examples of R² to R⁵ include, but not limited to, a methyl group, ethyl group, n-propyl group, isopropyl group, n-butyl group, isobutyl group, tert-butyl group, n-pentyl group, n-hexyl group, cyclohexyl group, n-octyl group, 2-hydroxyethyl group, phenyl group and 3-(trifluoromethyl)phenyl group.

The resist composition of the present invention may contain another organic base compound, particularly, a nitrogen-containing basic organic compound compounded as a quencher in an amount not deteriorating the effect of the present invention. Specific examples of such a nitrogen-containing basic organic compound include amines of the following formulae.

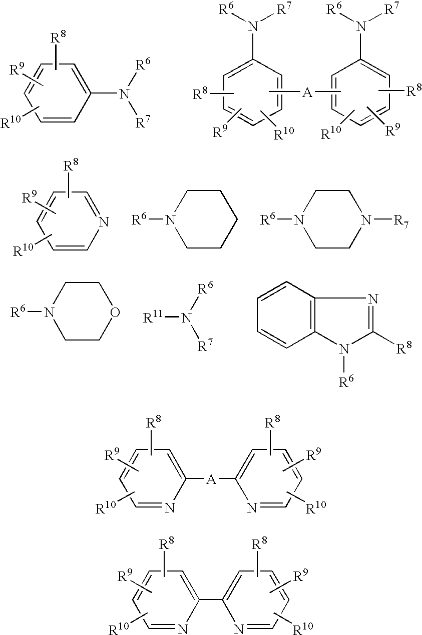

In the formulae, R⁶ and R⁷ represent each independently hydrogen, alkyl, cycloalkyl or aryl. The alkyl, cycloalkyl or aryl may be each independently substituted by a hydroxyl group, amino group or alkoxy group having 1 to 6 carbon atom. This amino group may be substituted by alkyl group having 1 to 4 carbon atom. This alkyl group preferably has about 1 to 6 carbon atoms, the cycloalkyl group preferably has about 5 to 10 carbon atoms, and the aryl group preferably has about 6 to 10 carbon atoms.

R⁸, R⁹ and R¹⁰ represent each independently hydrogen, alkyl, cycloalkyl, aryl or alkoxy. The alkyl, cycloalkyl, aryl or alkoxy may be each independently substituted by a hydroxyl group, amino group or alkoxy group having 1 to 6 carbon atom. The amino group may be substituted by an alkyl group having 1 to 4 carbon atoms. This alkyl preferably has about 1 to 6 carbon atoms, the cycloalkyl preferably has about 5 to 10 carbon atoms, the aryl preferably has about 6 to 10 carbon atoms, and the alkoxy preferably has about 1 to 6 carbon atoms.

R¹¹ represent an alkyl or cycloalkyl. The alkyl or cycloalkyl may be each independently substituted by a hydroxyl group, amino group or alkoxy group having 1 to 6 carbon atom. The amino group may be substituted by an alkyl group having 1 to 4 carbon atoms. This alkyl preferably has about 1 to 6 carbon atoms, and the cycloalkyl preferably has about 5 to 10 carbon atoms.

A represents an alkylene, carbonyl, imino, sulfide or disulfide. The alkylene may have about 2 to 6 carbon atoms, and may be linear or branched.

In R⁶ to R¹¹, those capable of manifesting a linear structure and a branched structure may take either structure.

Further, hindered amine compounds having a piperidine skeleton as disclosed in JP-A-11-52575 can also be used as a quencher.

It is preferable that the resist composition of the present invention contains 0.1 to 20 parts by weight of the acid generator, component (A) based on 100 parts by weight of the resin, component (B), becoming soluble in an alkali aqueous solution by the action of an acid.

It is also preferable that the resist composition of the present invention contains 0.001 to 10 parts by weight of the quaternary ammonium salt, component (C) based on 100 parts by weight of the resin, component (B) becoming soluble in an alkali aqueous solution by the action of an acid.

Further, this composition can contain also a small amount of various additives such as sensitizers, dissolution suppressing agents, other resins, surfactants, stabilizers, dyes and the like.

This resist composition usually takes a form of resist liquid composition containing components dissolved in a solvent, and applied on a substrate such as a silicon wafer and the like by an ordinary method. The solvent use here may be that dissolving the components, showing a suitable drying speed, and giving a uniform and smooth coated film after evaporation of the solvent. Those usually used in this field can be used. Examples thereof include glycol ether esters such as ethylcellosolve acetate, methylcellosolve acetate and propylene glycol monomethyl ether acetate; esters such as ethyl lactate, butyl acetate, amyl acetate and ethyl pyruvate; ketones such as acetone, methyl isobutyl ketone, 2-heptanone and cyclohexanone; cyclic esters such as γ-butyrolactone; alcohols such as 3-methoxy-1-butanol, and the like. These solvents can be used each alone or in combination of two or more.

A resist film applied on a substrate and dried is subjected to exposure treatment for patterning, then, subjected to heating treatment (PEB) for promoting a protective group-removing reaction, then, developer with an alkali developer. The alkali developer used here can be selected from various alkali aqueous solutions, and in general, aqueous solutions of tetramethylammonium hydroxide and (2-hydroxyethyl)trimethylammonium hydroxide (generally called coline) are often used.

The following examples will illustrate the present invention further specifically, but do not limit the scope of the present invention.

In the examples, % and parts representing the content or use amount are by weight unless otherwise state. The weight average molecular weight (Mw) and the polydispersion (Mw/Mn) is a valued measured by gel permeation chromatography using polystyrene as a standard.

### SYNTHESIS EXAMPLE 1

Production of Partial 1-ethoxyethylated Compound of polyhydroxystyrene

Into a 1 liter egg plant-formed flask, 40 g of poly(p-hydroxystyrene)(333 mmol in terms of p-hydroxystyrene unit) and 47 mg (0.25 mmol) of p-toluenesulfonic acid monohydrate were charged, and dissolved in 720 g of propylene glycol monomethyl ether acetate. This solution was distilled under reduced pressure at a temperature of 60° C. and a pressure of 10 Torr, and dehydrated under azeotrope. The weight of the solution after distillation was 337 g. This solution was moved into a 500 ml four-necked flask purged with nitrogen, into this was dropped 12.0 g (166 mmol) of ethyl vinyl ether, then, they were reacted at 25° C. for 5 hours. To this reaction solution was added 62.3 g of propylene glycol monomethyl ether acetate and 320 g of methyl isobutyl ketone, further, 240 ml of ion exchanged water was added and the mixture was stirred. Then, the mixture was allowed to stand still, and the organic layer part was removed. To this organic solution was added again 240 ml of ion exchanged water, the mixture was stirred, then, allowed to stand still to cause separation, thus performing washing. Washing and separation by ion exchanged water were conducted again. Then, the organic layer was removed and distilled under reduced pressure to cause azeotropic distillation of water and methyl isobutyl ketone with propylene glycol monomethyl ether acetate, giving a propylene glycol monomethyl ether acetate solution.

The resulted liquid is a solution of a resin in which a hydroxyl group of poly(p-hydroxystyrene) is partially 1-ethoxyethyl etherified, and this resin was analyzed by 1H-NMR, to find that 36% of hydroxyl groups had been 1-ethoxyethyl etherified. This resin is called resin A1.

### SYNTHESIS EXAMPLE 2

Synthesis of m-cresol Novolak Resin Excepting Lower Molecular Weight Body

Into a 1 L four-necked flask equipped with a reflux tube, stirring apparatus and thermometer were charged 218.3 g of m-cresol, 10.2 g of oxalic acid dihydrate, 68.7 g of 90% acetic acid and 203 g of methyl isobutyl ketone and the mixture was heated up to 80° C., and into this was dropped 143.2 g of a 37% formaldehyde aqueous solution over 1 hour. Thereafter, the mixture was heated up to reflux temperature and kept at the same temperature for 12 hours.

The resulted reaction solution was diluted with methyl isobutyl ketone, and washed with water and dehydrated, to obtain a 36.8% methyl isobutyl ketone solution of a novolak resin. 612 g of This resin solution was charged into a 5 L bottom-discharging type flask, diluted with 1119 g of methyl isobutyl ketone, and 1232 g of n-heptane was charged and the mixture was stirred at 60° C. and allowed to stand still, then, separated to obtain a novolak resin solution in the lower layer. This novolak resin solution was diluted with propylene glycol methyl ether acetate and then concentrated, to obtain a propylene glycol methyl ether acetate solution of a novolak resin. This resin is called resin A2.

This resin was measured by gel permeation chromatography (GPC) using polystyrene as a standard, to find that the area ratio of components having molecular weights of 1000 or less was 3.28% based on the total pattern area excepting unreacted monomers. This resin had a weight-average molecular weight of 9079.

Next, resist compositions were prepared using the following raw materials, in addition to resins in the above-mentioned synthesis examples, and evaluated.

Acid generator B1:

(5-toluylsulfonyloxyimino-5H-thiophen-2-ylidene)-(2-methylphenyl)acetonitrile

Quencher C1: tetrabutylammonium hydroxide

Quencher C2: tetramethylammonium hydroxide

Quencher C3: dicyclohexylmethylamine

Quencher C4: diisopropylaniline

### EXAMPLES 1 TO 6 AND COMPARATIVE EXAMPLES 1 AND 2

13.5 Parts (reduced by solid content) of a resin component mixed in a ratio (reduced by solid content) shown in Table 1, an acid generator B1 (0.1 part) and a quaternary ammonium salt as a quencher, in quantity and kind shown in Table 1, were dissolved in 40 parts of propylene glycol monomethyl ether acetate, and, then, filtrated through a fluorine resin filter having a pore diameter of 0.2 μm, to prepare a resist solution.

The above-mentioned resist solution was applied on a silicon wafer treated with hexamethyldisilazine using a spin coator so that the film thickness after drying was 1.49 μm. Pre-baking after application of the resist solution was conducted on a hot plate at 90° C. for 60 seconds. The wafer carrying thus formed resist film was exposed to line and space pattern using a reduction projection exposing machine having an exposure wavelength of 365 nm (i line) [“NSR-2005i9C” manufactured by Nikon Corp., NA=0.57, σ=0.8] while gradually changing the exposure amount. Then, on a hot plate, post exposure baking was conducted at 110° C. for 60 seconds. Further, paddle development was conducted using a 2.38% tetramethylammonium hydroxide aqueous solution (developer SOPD manufactured by Sumitomo Chemical Co., Ltd.) for 60 seconds. The pattern after development was observed by a scanning electron microscope, and the effective sensitivity, resolution and profile were measured by the following methods. The results are shown in Table 2.

Effective sensitivity: It is represented by the exposure amount at which 1.0 μm line and space pattern is 1:1.

Resolution: It is represented by the minimum dimension of line and space pattern separating at the exposure amount of the effective sensitivity.

TABLE 1

| | | Acid | | |
|---|---|---|---|---|
| No. | Resin | generator | Quencher | |
| Example 1 | A1/100% | B1 | C1/0.005 | part |
| Example 2 | A1/50% A2/50% | B1 | C1/0.005 | part |
| Example 3 | A1/50% A2/50% | B1 | C2/0.0015 | part |
| Comparative | A1/50% A2/50% | B1 | C3/0.005 | part |
| example 1 | | | | |
| Comparative | A1/50% A2/50% | B1 | C4/0.005 | part |
| example 2 | | | | |

TABLE 2

| | Effective | |
|---|---|---|
| | sensitivity | Resolution |
| No. | [msec/cm²] | [μmm] |
| Example 1 | 54 | 0.27 |
| Example 2 | 46 | 0.45 |
| Example 3 | 42 | 0.5 |
| Comparative example 1 | 167 | 0.95 |
| Comparative example 2 | 85 | 0.6 |

The chemical amplification type positive resist composition of the present invention can attain high sensitivity while maintaining high resolution.

What is claimed is:

1. A chemical amplification type positive resist composition comprising
(A) a compound of the following formula (I): 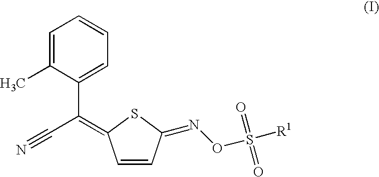
wherein, R¹ represents a hydrocarbon group optionally having a substituent containing an oxygen atom or nitrogen atom or being optionally substituted by a halogen atom;
(B) a resin which itself is insoluble or poorly soluble in an alkaline aqueous solution but becomes soluble in an alkaline aqueous solution by the action of an acid; and
(C) a quaternary ammonium salt.

2. The chemical amplification type positive resist composition according to claim 1, wherein the component (B) is a resin containing a polymerization unit having a structure formed by partially protecting a phenolic hydroxyl group with a 1-ethoxyethyl group.

3. The chemical amplification type positive resist composition according to claim 1, wherein the component (B) is a resin obtained by partially protecting a hydroxyl group in polyvinylphenol with a 1-ethoxyethyl group.

4. The chemical amplification type positive resist composition according to claim 1, wherein the component (B) is a resin obtained by partially protecting a hydroxyl group in a novolak resin with a 1-ethoxyethyl group.

5. The chemical amplification type positive resist composition according to claim 1, wherein the component (A) is a compound of the formula (I), in which R¹ represents a n-propyl group, n-butyl group, n-octyl group, toluyl group, 2,4,6-trimethylphenyl group, 2,4,6-triisopropylphenyl group, 4-dodecylphenyl group, 4-methoxyphenyl group, 2-naphthyl group, benzyl group, or a group of the following formula (II).

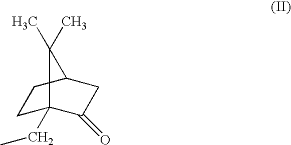

6. The chemical amplification type positive resist composition according to claim 1, wherein the component (C) is a compound of the following general formula (III) 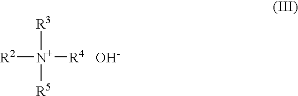
wherein, R² to R⁵ each independently represent a hydrocarbon group optionally having a substituent containing an oxygen atom or nitrogen atom, or being optionally substituted by a halogen atom, provided that R² to R⁵ groups can together form a cyclic structure.

7. The chemical amplification type positive resist composition according to claim 1, wherein the component (C) is a compound selected from a group consisting of tetramethylammonium hydroxide, tetra-n-butylammonium hydroxide, tetra-n-hexylammonium hydroxide, tetra-n-octylammonium hydroxide, phenyltrimethylammonium hydroxide, 3-(trifluoromethyl)-phenyltrimethylammonium hydroxide and (2-hydroxyethyl)trimethylammonium hydroxide.
